(19) United States
(12) Patent Application Publication
(10) Pub. No.: US 2005/0000428 A1
(43) Pub. Date: Jan. 6, 2005

(54) Method and apparatus for vaporizing and delivering reactant

(76) Inventors: Eric J. Shero, Phoenix, AZ (US); Mohith E. Verghese, Phoenix, AZ (US)

Correspondence Address: KNOBBE MARTENS OLSON & BEAR LLP, 2040 MAIN STREET, FOURTEENTH FLOOR, IRVINE, CA, 92614, US

(21) Appl. No.: 10/846,206

(22) Filed: May 14, 2004

Related U.S. Application Data
(60) Provisional application No. 60/512,931, filed on May 16, 2003.
(60) Provisional application No. 60/537,191, filed on Jan. 19, 2004.

(51) Int. Cl. C23C 16/00

(52) U.S. Cl. 118/715

(57) ABSTRACT

A reactant supply apparatus comprises a vessel with a gas inlet and a gas outlet. Gas lines are connected to the gas inlet or the gas outlet. A plurality of components are positioned along the gas lines. A first heating device is provided for heating the vessel. Apparatus and methods are provided for biasing the temperature of at least one of the plurality of components to a temperature higher than the vessel.

### REFERENCE TO RELATED APPLICATIONS

This application claims the priority benefit under 35 U.S.C. § 119(e) of U.S. Provisional Application 60/512,931, filed May 16, 2003 and U.S. Provisional Application 60/537,191, filed Jan. 19, 2004.

### BACKGROUND OF THE INVENTION

1. Field of the Invention

The present invention relates to the use of vapor phase chemical reactants. In particular, the present invention relates to feeding a vaporized reactant into a reaction chamber.

2. Description of the Related Art

During semiconductor processing, various reactant gases are fed into the reaction chamber. In some applications, the reactant gases are stored in gaseous form in a reactant source vessel. In such applications, the reactant vapors are often gaseous at ambient (i.e. normal) pressures and temperatures. Examples of such gases include nitrogen, oxygen, hydrogen, and ammonia. However, in some cases, the vapors of source chemicals that are liquid or solid at ambient pressure and temperature are used. These substances may have to be heated to produce sufficient amounts of vapor for the reaction process. For some solid substances, the vapor pressure at room temperature is so low that they have to be heated to produce a sufficient amount of reactant vapor and/or maintained at very low pressures. Once vaporized, it is important that the vapor phase reactant is kept at or above the vaporizing temperature through the processing system so as to prevent undesirable condensation in the valves, filters, conduits and other components associated with delivering the vapor phase reactants to the reaction chamber. Vapor phase reactant from such naturally solid or liquid substances are useful for chemical reactions in a variety of other industries.

In some conventional arrangements, the source vessel is fitted inside the same pressure shell as the reaction chamber. As a result, the size of the pressure shell or vacuum vessel has to be increased. Furthermore, the solid or liquid reactant may come in contact with air during loading and maintenance operations, which may lead to contamination of the solid or liquid reactant when the vacuum of the reaction chamber is broken. Moreover, during loading and maintenance operations, there will also be constant evaporation of the solid or liquid reactant and at least some of the vaporized precursor will be drained via an outlet channel and some material will be deposited on the channel walls.

Atomic layer deposition (ALD) is a known process in the semiconductor industry for forming thin films of materials on substrates such as silicon wafers. In many applications, ALD uses a solid and/or liquid source chemical as described above. ALD is a type of vapor deposition wherein a film is built up through self-saturating reactions performed in cycles. The thickness of the film is determined by the number of cycles performed. In an ALD process, gaseous precursors are supplied, alternatingly and repeatedly, to the substrate or wafer to form a thin film of material on the wafer. One reactant adsorbs in a self-limiting process on the wafer. A subsequent reactant pulse reacts with the adsorbed material to form a single molecular layer of the desired material. Decomposition may occur through reaction with an appropriately selected reagent, such as in a ligand exchange or a gettering reaction. In a typical ALD reaction, no more than a molecular monolayer forms per cycle. Thicker films are produced through repeated growth cycles until the target thickness is achieved.

In an ALD process, one or more substrates with at least one surface to be coated and reactants for forming a desired product are introduced into the reactor or deposition chamber. The one or more substrates are typically placed on a wafer support or susceptor. The wafer support is located inside a chamber defined around the reactor. In one type of reactor, the suscpetor may move up and down within the vacuum chamber. When the susceptor is in the upper position, it creates the lower surface of the reactor. The wafer is heated to a desired temperature above the condensation temperatures of the reactant gases and often below the thermal decomposition temperatures of the reactant gases.

A characteristic feature of ALD is that each reactant is delivered to the substrate in a pulse until a saturated surface condition is reached. As noted above, one reactant typically adsorbs in a first pulse on the substrate surface and a second reactant subsequently reacts with the adsorbed species during the second pulse. To obtain a self-limiting growth, vapor phase reactants are kept separated by purge or other removal steps between sequential reactant pulses. Since growth of the desired material does not occur during the purge step, it can be advantageous to limit the duration of the purge step. A shorter duration purge step can increase the available time for adsorption and reaction of the reactants within the reactor, but the vapor phase reactants cannot be allowed to mix at the risk of CVD reactions destroying the self-limiting nature of the deposition. As the growth rate is self-limiting, the rate of growth is proportional to the repetition rate of the reaction sequences, rather than to the temperature or flux of reactant as in CVD.

### SUMMARY OF THE INVENTION

It is an aim of the present invention to eliminate at least some of the drawbacks of the prior art and to provide a new method and apparatus for feeding gas phase reactants from liquid or solid sources into a vapor processing reactor.

In one embodiment of the present invention, a reactant source vessel and a reaction chamber are positioned within separate enclosures, which can be separately and individually evacuated to allow for independent operation and maintenance. The reactant source vessel is provided with a gas inlet for feeding carrier gas into the reactant source vessel and a gas outlet for withdrawal of gaseous reactant. In modified embodiments, reactant from the reactant source vessel may be drawn with a vacuum into the reaction chamber without a carrier gas. In one embodiment, the reactant source vessel is placed within a source enclosure and heated to the vaporizing temperature by using a heating device fitted within the enclosure. The vaporized reactant is conducted from the reactant source vessel into the gas phase reaction chamber via a first conduit interconnecting the reactant source vessel and the reaction chamber. Within the source enclosure is a second heating device that is controllable independently from the first heating device. The second heating device is used to bias certain components in the source enclosure to a temperature higher than the temperature of the reactant source vessel. In the preferred embodiment, the first heating device is a radiant heater.

According to another aspect of the invention, a system comprises a reactant source vessel and a reaction chamber. The reactant source vessel and the reaction chamber are positioned in separate enclosures which can be individually evacuated. The reactant source vessel and the reaction chamber are preferably thermally isolated from each other and interconnected with a first conduit comprising at least one valve. In the first conduit, the flow or diffusion of reactant from the reactant source vessel to the reaction chamber can be prevented by forming a gas phase barrier of a gas flowing in the opposite direction to the reactant flow in the conduit and the valve can be used for separating the gas spaces of the reactant source vessel and the reaction chamber during evacuation of either or both of these components. The reactant source vessel comprises at least one inlet for feeding gas into the reactant source and at least one outlet for withdrawing gas from the reactant source vessel. The outlet of the reactant source vessel communicates with the reaction chamber. In one embodiment, the gas phase barrier is formed at least partially within the enclosure surrounding the reaction chamber.

In another embodiment of the invention, a reactant source vessel is positioned within a reactant source cabinet. Portions of the conduits and valves upstream and/or downstream of the reactant source vessel are biased to a higher temperature than the reactant source cabinet. In the illustrated embodiment, valves are heated by one or more hot plates that are positioned within the reactant source cabinet and are configured to allow the temperature of such valves to be separately controlled from the temperature of the reactant source vessel and/or maintained at a higher temperature than the reactant source vessel.

In another embodiment of the invention, a reactant supply apparatus comprises a reactant source cabinet and a reactant source vessel with a gas inlet and a gas outlet positioned in the reactant source cabinet. Gas lines are connected to the gas inlet and the gas outlet and positioned in the reactant source cabinet. A plurality of components are positioned along the gas lines within the reactant source cabinet. A radiant heating device is also positioned within the reactant source cabinet. At least a portion of the gas lines or at least one of the plurality of components have a higher absorptivity than the reactant source vessel.

In another embodiment of the invention a reactant supply apparatus comprises a reactant source cabinet and a reactant source vessel with a gas inlet and a gas outlet positioned in the reactant source cabinet. Gas lines are connected to the gas inlet and the gas outlet and are positioned in the reactant source cabinet. A plurality of components are positioned along the gas lines within the reactant source cabinet. A radiant heating device is positioned within the reactant source cabinet. At least a portion of the gas lines or at least one of the plurality of components have a higher absorptivity than the reactant source reactant source cabinet.

In another embodiment of the invention, an apparatus for supplying a vaporized reactant to a reaction chamber comprises a source of the vaporized reactant, a plurality of components through which the vaporized reactant flow towards the reaction chamber, and a radiant heat source for heating at least some of the plurality of components. At least one of the plurality of components is coated with a coating that reduces its reflectivity or increases its absorptivity.

In another embodiment of the invention, a reactant supply apparatus comprises a vessel with a gas inlet and a gas outlet. Gas lines are connected to the gas inlet or the gas outlet. A plurality of components are positioned along the gas lines. The apparatus also includes a first heating device for heating the vessel and means for biasing the temperature of at least one of the plurality of components to a temperature higher than the vessel.

These and other objects, together with the advantages thereof over known processes and apparatuses which shall become apparent from the following specification, are accomplished by the invention as hereinafter described and claimed.

### BRIEF DESCRIPTION OF THE DRAWINGS

FIG. 1 is a perspective view a reactant source assembly and a reactor chamber assembly, constructed in accordance with a preferred embodiment of the present invention.

FIG. 2 is in a schematic illustration of the reactant source assembly of FIG. 1.

FIG. 3 is a perspective view the reactant source assembly of FIG. 1, shown with a side door open and the outer panels removed for purposes of illustration.

FIG. 4 is a sectional side view of one embodiment of a source vessel.

FIG. 5 is a perspective view of a reactant source assembly in accordance with another embodiment of the present invention, shown with the side door removed.

FIG. 6 is another perspective view of the reactant source assembly of FIG. 6.

FIG. 7 is a schematic illustration of the reactant source assembly of FIG. 6.

FIG. 8 is a perspective view of a particular embodiment of inert gas valving arrangement, shown over the reaction chamber.

FIG. 9 is another perspective of the inert gas valving arrangement of FIG. 9.

### DETAILED DESCRIPTION OF THE PREFERRED EMBODIMENT

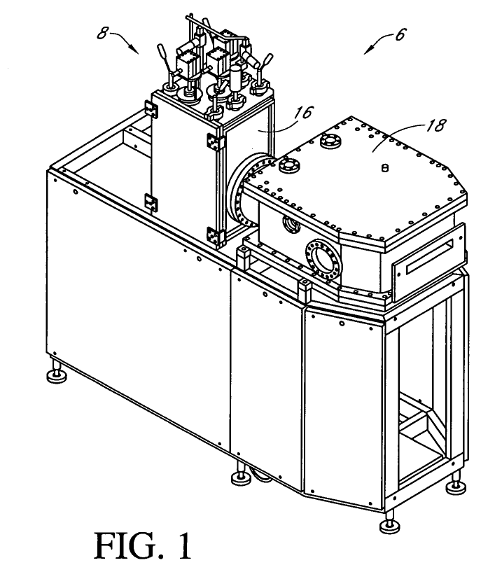

FIGS. 1-3 illustrate an exemplary embodiment of a processing system 6 comprising a reactant source apparatus 8 for feeding a gas phase reactant generated from a reactant source vessel 10 into a gas phase reaction chamber 12. A reactant (not shown), which may be liquid or solid under standard (i.e., room temperature and atmospheric pressure) conditions, is vaporized within the reactant source vessel 10, which may be maintained at or above a vaporizing temperature. The vaporized reactant is then fed into the reaction chamber 12. The reactant source vessel 10 and the reaction chamber 12 are located in a reactant source cabinet 16 and a reaction chamber vessel 18, respectively, which are preferably individually evacuated and/or thermally controlled. As will be explained in more detail below, this can be achieved by providing these components with separate cooling and heating devices, insulation and/or isolation valves and associated piping.

The exemplary reactant source apparatus 8 is particularly suited for delivering vapor phase reactants to be used in a vapor phase reaction chamber. In one preferred embodiment, the vapor phase reactants are used for deposition (e.g., CVD) and more preferably for Atomic Layer Deposition, ALD, (formerly known as Atomic Layer Epitaxy, abbreviated ALE). In ALD, vapor phase reactants are fed into the reaction chamber in the form of alternate gas phase pulses that are preferably separated by removal steps (e.g., purging). ALD is typically characterized by self-saturating, adsorption reactions that take place within a temperature window that lies above the condensation temperature of the vapor phase reactants and below a thermal decomposition limit of the reactants. Typically, less than or about one molecular monolayer of reactant is deposited per cycle. In ALD, it is generally advantageous to keep reactants separated from each other until they are allowed to react on the surface to be coated. Mixing of the vapor phase reactants in the processing system upstream of the reaction surface may cause undesirable deposition and gas-phase reactions.

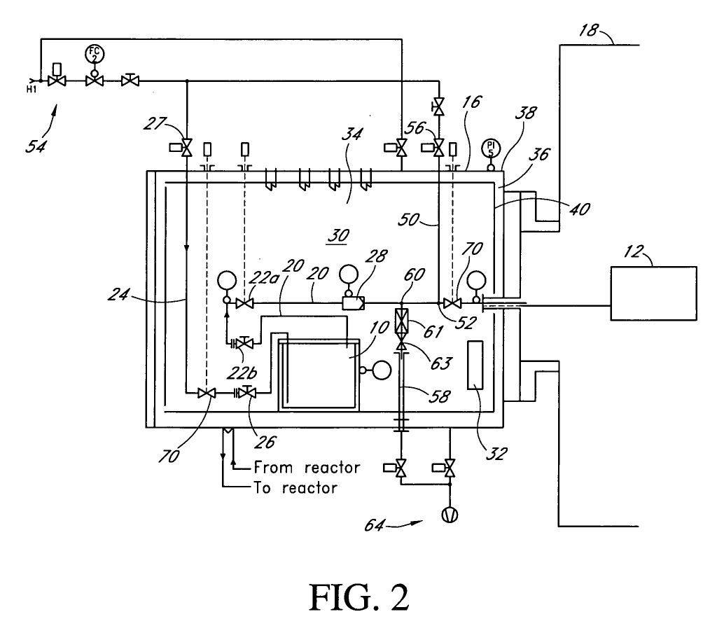

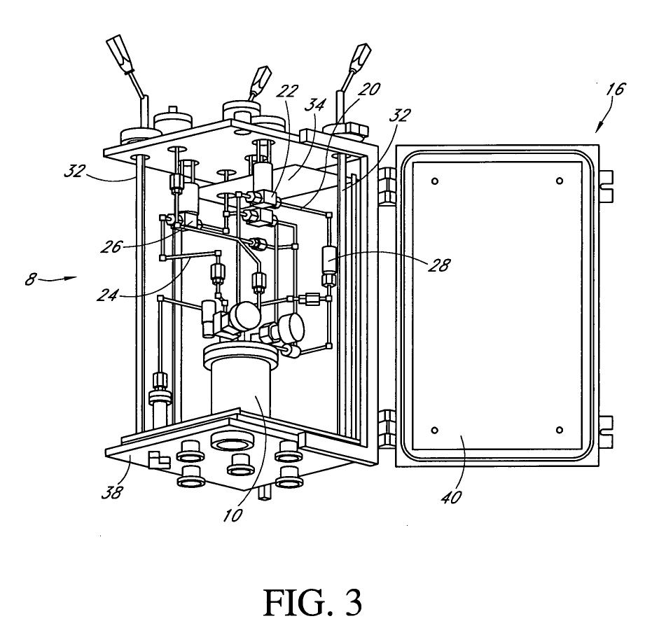

As seen in FIGS. 2 and 3, the reactant source vessel 10 and the reaction chamber 12 are adapted to be in selective communication with each other through a first conduit 20 so as to feed the gas phase reactant from the reactant source vessel 10 to the reaction chamber 12 (preferably an ALD reaction chamber). The first conduit 20 includes at least one isolation valve 22, which may be used for separating the gas spaces of the reactant source vessel 10 and the reaction chamber 12 during evacuation and/or maintenance of either or both of the reactant source vessel 10 and the reaction chamber vessel 18.

As will be explained in more detail below, it is also possible to arrange for “inert gas valving or a diffusion barrier” in a portion of the first conduit 20 to prevent flow of reactant from the reactant source vessel 10 to the reaction chamber 12 by forming a gas phase barrier by flowing gas in the opposite direction to the normal reactant flow in the first conduit 20. See T. Suntola, Handbook of Crystal Growth III, Thin Films and Epitaxy, Part B: Growth Mechanisms and Dynamics, ch. 14, Atomic Layer Epitaxy, edited by D. T. J. Hurle, Elsevier Science V. B. (1994), pp. 601-663, the disclosure of which is incorporated herein by reference. See especially, pp. 624-626. Also see U.S. patent application Ser. No. 09/835,931, filed Apr. 16, 2001 and entitled METHOD OF GROWING A THIN FILM ONTO A SUBSTRATE, the disclosure of which is incorporated herein by reference.

In the illustrated embodiment of FIGS. 1-3, a substantial length of the first conduit 20 is contained within the reactant source cabinet 16. Thus, the first conduit 20 will inherently receive some heat to prevent condensation of reactant vapors.

Inactive or inert gas is preferably used as a carrier gas for the vaporized solid or liquid reactant. The inert gas (e.g., nitrogen or argon) may be fed into the reactant source vessel 10 through a second conduit 24. The reactant source vessel 10 includes at least one inlet for connection to the second conduit 24 and at least one outlet for withdrawing gas from the reactant source vessel 10. The outlet of the reactant source vessel 10 is connected to the first conduit 20. The reactant source vessel 10 can be operated at a pressure in excess of the pressure of the reaction chamber 12. Accordingly, the second conduit 24 includes at least one isolation valve 26, which can be used for separating the gas spaces of the reactant source vessel 10 during maintenance of the reactant source vessel 10. As will be explained in more detail below, a control valve 27 for the second conduit 24 is preferably positioned in the second conduit 24 outside of the reactant source cabinet 16.

In order to remove dispersed liquid droplets or solid particles, the exemplary embodiment includes a purifier 28 through which the vaporized reactant is conducted. The purifier 28 may comprise a purifying device, such as, for example, mechanical filters, ceramic molecular sieves and/or electrostatic filters capable of separating dispersed liquid droplets or solid or particles or molecules of a minimum molecular size from the reactant gas flow. As will be explained in more detail below, a second purifier may be placed within the source vessel.

As mentioned above, the reactant source vessel 10 is positioned within the reactant source cabinet 16. The interior space 30 of the reactant source cabinet 16 is advantageously kept at a reduced pressure to promote radiant heating of the components within the reactant source cabinet 16 and to thermally isolate such components from each other to facilitate uniform temperature fields. In one embodiment, the reduced pressure is in the range of about 1 mTorr to about 10 Torr and often about 500 mTorr. However, in modified embodiments, the reactant source cabinet 16 may not be evacuated and may include convection enhancing devices (e.g., fans, cross-flows etc.). In the exemplary embodiment, the reactant source cabinet 16 includes a heating device 32, which preferably comprises radiation heaters (e.g., tubular resistive heater elements). The exemplary reactant source cabinet 16 also includes one or more reflector sheets 34, which are preferably configured to surround the components within the source cabinet to reflect the radiant heat generated by the heating device 32 to the components positioned within the reactant source cabinet 16. In one embodiment, the operational temperature of the reactant source vessel 10 is within the range of approximately 20° C. to 300° C. degrees centigrade, and in other embodiments to within 20° C. and 500° C. degrees centigrade. The heating device 32 of the reactant source cabinet 16 is configured to maintain an interior space of the reactant source cabinet 16 at or above these operational temperatures.

As seen in FIG. 2, the exemplary reactant source cabinet 16 includes a cooling jacket 36 which is formed within an outer wall 38 and inner wall 40 of the source cabinet 16. The water jacket 36 allows the outer surface 38 of the reactant source cabinet 16 to be maintained at or near ambient temperatures. In other embodiments, a cooling jacket may be welded to the external walls of the reactant source cabinet 16 itself.

As mentioned above, in order to prevent or reduce gas flow from the reactant source vessel 10 between the pulses, it is possible to form an inactive gas barrier in the first conduit 20 (i.e., inert gas valving). With reference to the exemplary embodiment illustrated in FIG. 2, the gas barrier can be formed by feeding inactive gas into the first conduit 20 via a third conduit 50, which is connected to the first conduit 20 at a first connection point 52. The third conduit 50 is connected to an inert gas source 54. A control valve 56 may be positioned in the third conduit 50, preferably outside of the source cabinet 16. During the time intervals between the feeding of vapor-phase pulses from the reactant source vessel 10, inactive gas is preferably fed into the first conduit 20 through the third conduit 50. This gas can be withdrawn from the first conduit 20 via a fourth conduit 58, which connected to the first conduit at a second connection point 60. In the illustrated embodiment, the second connection point 60 is located upstream of the first connection point 52 (i.e., closer to the reactant source vessel 10). In this manner, an inert gas flow of an opposite direction to the normal reactant gas flow is achieved (between reactant pulses) in the first conduit 20 between the first and second connection points 52, 60. The third conduit 50 is preferably maintained at a temperature equal to or higher than the condensation temperature of the vapor-phase reactant and, in certain embodiment, at a temperature equal to or lower than the reaction temperature. As such, in the illustrated embodiment, the second connection point 60 and at least a portion of the third conduit 50 are positioned in the reactant source cabinet 16 to avoid the need for external or separate heating devices. Advantageously, the fourth conduit 58 is in communication with a evacuation source 64 (i.e., an evacuation pump). In one embodiment, the fourth conduit 58 comprises an open gas flow channel (i.e., it does not contain valves that can close shut). However, in the illustrated embodiment, a valve 63 may be used to reduce material loss during a pulse (e.g., by closing the valve 63 during a reactant pulse) In this manner, reactant flow to portions of the fourth conduit 58 located outside the reactant source cabinet 16 is reduced. Reactant flow outside the reactant source cabinet 16 tends to condense and clog the conduit 58. Accordingly, the fourth conduit 58 preferably includes at least one restriction 61 for limiting loss of vapor phase reactant during reactant pulses.

An advantage of the illustrated embodiment is that the control valves 27, 56 for the inert carrier gas and/or the inert purge gas through the first conduit 20 are positioned outside of the reactant source cabinet 16. In this manner, the control valves 27, 56 may be spared from the damage that may be caused by high temperature or cyclic heating and cooling.

In the illustrated embodiment, the various conduits are placed at least partially within the reactant source cabinet 16. In some embodiments, there is a constant flow of nitrogen (or other inert gas) in some or all of the conduits and/or constant control of the pressure. This arrangement advantageously reduces health hazards caused by any leaks and processing problems caused by air leaking into the equipment.

As mentioned above, maintenance valves 22, 26 are provided in the first and second conduits 20, 24. Such maintenance valves 22, 26 can be used for switching or recharging the reactant source vessel 10 with liquid or solid reactant or maintenance or repair of the vessel 10. Additional control or switching valves 70 may also be placed along the conduits 20, 24 within the reactant source cabinet 16 and may be used during heating and cooling or isolation of the reactant source cabinet 16. To accommodate the high temperatures within the reactant source cabinet 16, these valves 70 may be constructed in such a way that they are activated by a pneumatic actuator that is placed outside the reactant source cabinet 16.

In one embodiment, the reactant source vessel 10 may be formed into a separate modular unit which can be replaced by a similar unit when a new loading of the reactant chemical is needed. In such an arrangement, the above mentioned source vessel 10 may be detachably connected to the first and the second conduits 20, 24.

The reactant source vessel 10 can be exchanged without allowing the source chemical to contact air. This may be carried out with the aid of the isolation valves 22, 26 and nitrogen pressure in the conduits. The reactant source vessel 10 may also changed without breaking of the vacuum in the reaction chamber 12. This can be effected by closing the isolation valves 22, 26 and by forming an inert gas diffusion barrier against the flow of residual reactant gas from the reactant source vessel 10 towards the reaction chamber 12.

It should be appreciated that in other embodiments more than one reactant source vessel and associated conduits may be positioned in the reactant source cabinet 16. In other embodiments, the reactant source cabinet 16 may be divided into sub-components with separate heating devices, which makes it possible to operate different source vessels at different temperatures. Preferably, however, separate reactant source cabinets 16 for separate reactant source vessels are used.

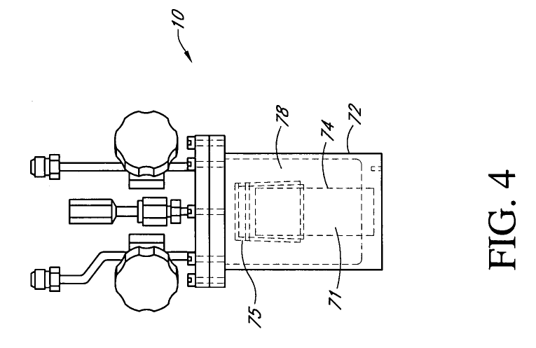

The reactant source vessel 10 of an exemplary embodiment is shown in more detail in FIG. 4. However, it should be appreciated that apparatus 8 described herein may be used with other types of reactant source vessels for liquid or solid source reactants. That is, the reactant source vessel 10 of FIG. 4 is merely one example of a reactant source vessel that may be used with the embodiments described herein.

With reference to FIG. 4, the exemplary reactant source vessel 10 comprises a glass crucible or ampoule 71 for holding solid source chemical, which prevents direct contact between the chemical contained therein and a steel container 72 surrounding the ampoule 71. The ampoule 71 comprises a casing 74 and a cover or lid 75, which may be joined together by a conical joint having polished surfaces. In the exemplary embodiment, the lid 75 may include a ceramic sinter whose main task is to prevent carrier gas flow fed into the vessel from directly hitting the powdery reactant. Between the reactant source vessel 10 and the glass ampoule, there is formed a gas space 78, which preferably has a larger volume than one individual gas phase pulse and more preferably at least 5 times such a volume. In this manner, the gas space 78 will be capable of diluting the concentration of the reactant pulse and to maintain a constant concentration of the vapor phase pulse. The gas space 78 in which the vaporized reactant is collected can be formed around the glass ampoule 71, e.g., by the space between the steel container 72 and the ampoule 71. The surfaces defining the gas space 78 are maintained at a temperature equal to or higher than the vaporizing temperature to avoid condensation of the reactant. In the illustrated embodiment, the gas space 78 is maintained at such a temperature by being positioned within the reactant source cabinet 16.

The container 72 may be made of a metal selected from the group of stainless steel, nickel, titanium and aluminum, whereas the ampoule may be made of glass or similar material. The container 72 can also be made of a material which has an additional non-reactive surface coating to prevent corrosion of the material.

In this embodiment, in order to free the vaporized reactant from liquid or solid impurities, the evaporated reactant can be purified in a first purifier and then collected in the gas space 78. The first purifier may be positioned in the lid 75 and may comprise, e.g., a filter, a semi-permeable membrane or similar filter capable of removing fines having a size of less than 0.01 μm, preferably less than 0.005 μm. In one embodiment, the purifier comprises a commercial filtration unit, which has a filter comprising a membrane made of ceramics, steel or inert metal. The filter may be cleaned by heating it to a temperature in excess of the normal operating temperature and by pumping away the vaporized substance. The filter preferably removes 99.9999999% of particles larger than 0.003 μm.

With reference back to FIGS. 1-3, in one embodiment of use, the heating device 32 in the reactant source cabinet 16 is used to maintain the reactant in the reactant source vessel 10 at or above the vaporizing temperature to vaporize the source material. In the preferred embodiment, the heating device 32 comprises a radiant heater, which is placed with a cabinet 16 that is evacuated and utilizes reflectors 34 to reflect the radiant energy to the reactant source vessel 10 positioned within the cabinet 16. The vaporized reactant is conducted from the reactant source vessel 10 through a first conduit 20 that may include one or more purifiers 28 to remove impurities. In an embodiment utilizing the reactant source vessel 10 described above with respect to FIG. 4, the vaporized reactant is collected in a gas space 78 and may pass through a second filter arranged in the lid 75. The vaporized reactant in the first conduit 20 is feed into the reactant chamber 12. The inert gas valving described above may be used to sequentially pulse the vaporized reactant, alternately with one or more additional reactants (not shown) into the reaction chamber 12.

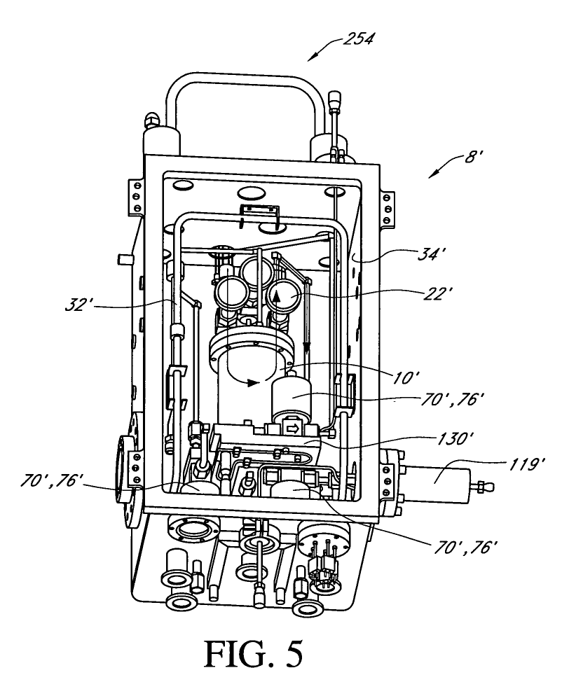

FIGS. 5-7 illustrate an apparatus 8′ in which like numbers will be used to describe components similar to the components described above. As with the previous embodiments, the illustrated embodiment includes a reactant source vessel 10′, a reaction chamber 12′, a reactant source cabinet 16′, a reaction chamber vessel 18′, a heating device 32′, a first conduit 20′, a second conduit 24′, isolation valves 22′, 26′ and control valves 70′, 76′. Additional illustrated components include a cooling inlets/outlets 252 for the cooling jacket, an electrical connection 254 for the main heater 32′ and a pneumatic feed 256 through for valves.

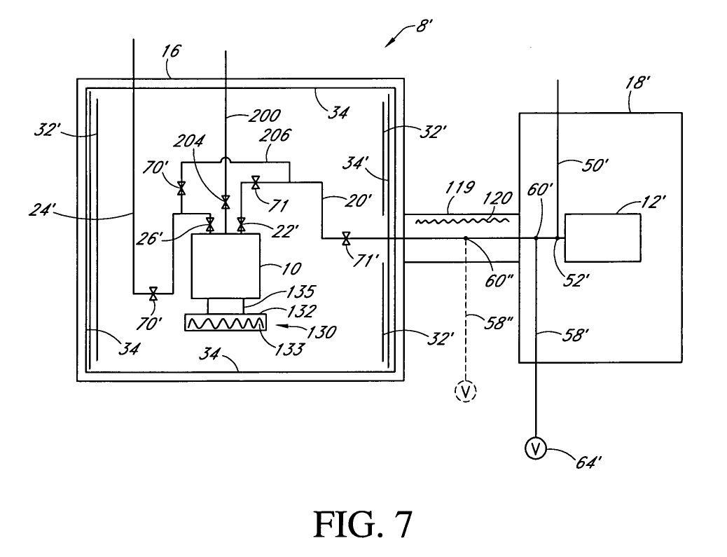

As seen in FIG. 7, in this embodiment, the inert gas diffusion barrier is positioned outside of the reactant source cabinet 16′ and at least partially in the reaction chamber vessel 18′. That is, the connection point 52′ between the first conduit 20′ and the third conduit 50′ is positioned inside the reaction chamber vessel 18′. In addition, the second connection point 60′ between the fourth conduit 58′ and the first conduit 20′ is also positioned outside the reactant source cabinet 16′ and, in the illustrated embodiment, it also is positioned inside the reaction chamber vessel 18′. In this manner, the diffusion barrier (i.e., the portion of the first conduit 20′ between the first connection point 52′ and the second connection point 60′) is in the reaction chamber vessel 18′ and located closer to the reaction chamber 12′ as compared to the embodiment of FIGS. 1-3. In one embodiment, the diffusion barrier is within about 12 inches of inlet the reaction chamber 12 and in other embodiment within about 6 inches. Accordingly, the flow into the reaction space can be shut off more quickly resulting in quicker pulsing. In a modified embodiment, the diffusion barrier may be located partially outside the reaction chamber vessel 18′ (e.g., as illustrated by the dashed line in FIG. 7, the second connection point 60″ may be located between the reactant source cabinet 16′ and reaction chamber vessel 18′). An advantage to this embodiment is that at least a portion of the diffusion barrier may be maintained at a lower temperature and/or higher pressure (by being further upstream), which creates a more effective diffusion barrier by reducing the precursor diffusion. In addition, in some embodiments, more than one reactant may be used. In such embodiments, the reactants may be passed through a common plenum or “mixer”. By positioning the diffusion barrier closer to the mixer, the length of line that must outgas the residual of the previous precursor pulse is reduced. In addition, this length of line may be kept at an elevated temperature which enhances desorption.

With reference to FIGS. 5-7, in the illustrated embodiment, the reactant source vessel 10′ is connected to a pressure release line 200, which is preferably provided with a pressure release valve 204. A connection conduit 206 is preferably provided between the second conduit 24′ and the first conduit 20′. Control valves 71 (are preferably provided in the first conduit 20′ upstream and/or downstream of the connection point between the connection conduit 206 and the first conduit 20′.

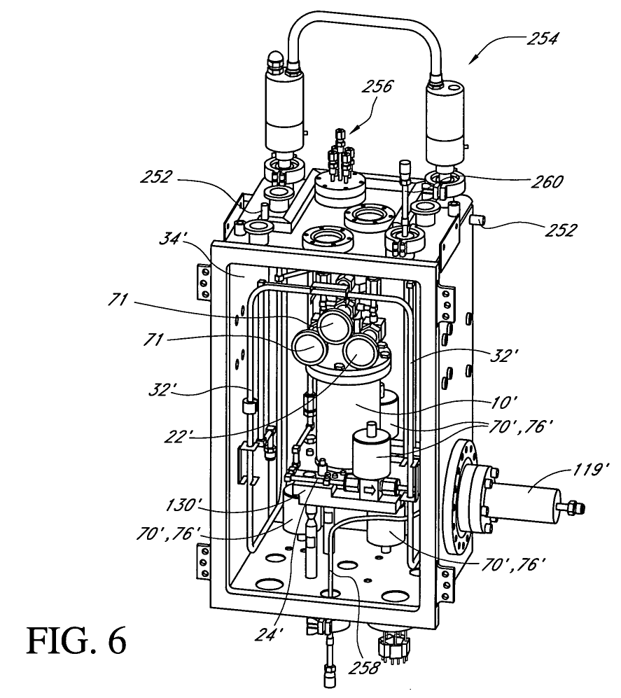

In the illustrated embodiment, at least a portion of the first conduit 20′ is positioned between the reactant source cabinet 16′ and the reaction chamber vessel 18′. This portion of the first conduit 20′ is positioned within a feedthrough chamber 119, which includes a separate heater 120 for heating the portion of the first conduit 20′ between the source cabinet 16′ and the reaction chamber vessel 18′. In a preferred embodiment, the feedthrough chamber 119 comprises a stainless steel tube, which surrounds an aluminum (or other conductive material) block. The separate heater 120 comprises a resistive heater mounted within the block. The conduit 20′ extends through the block and is heated by resistive heater 120. The resistive heater 120 may be provided power through an electrical conduit 258 (see FIG. 6).

The illustrated embodiment also includes a hot plate 130, which includes a support member 132 and a separate heating device 133 (e.g., a resistive heating coil embedded in the support member) for heating the support member 132. Advantageously, the source vessel 10′ is at least partially thermally isolated from the hot plate 130. In the illustrated embodiment, the source vessel 10′ is thermally isolated from the hot plate 130 by supporting the source vessel 10′ above the hot plate 130 on one or more spacer supports 135. In other embodiments, the source vessel 10′ may be thermally isolated from the hot plate 130 by placing insulation between the reactant source vessel 10′ and the hot plate 130. In still other embodiments, the reactant source vessel 10′ may be physically separated from the hot plate 130 within the reactant source cabinet 16′. In such embodiments, the hot plate 130 may not physically support the reactant source vessel 10′ within the reactant source cabinet 16′. For example, the hot plate 130 may be positioned above the source vessel 10′. With reference to FIG. 6, an electrical conduit 260 may extend through the reactant source cabinet 16′ for supplying power to the heating device 133.

As shown in FIG. 6, certain components of the reactant source cabinet 16′ are thermally coupled to a component that is heated independently of the main source cabinet heater(s). In the illustrated embodiment, the independent heated component comprises the hot plate 130. For example, in the illustrated embodiment, the control valves 70′, 76′ and portions of the conduits 20′, 24′, 206 are thermally coupled to the hot plate 130. These components may be thermally coupled to the hot plate 130 in a variety of manners, such as, for example, physically attaching and/or coupling these components to the plate. In this manner, the temperature of these components (herein “secondary components”) may be biased higher than the temperature of the other components in the reactant source cabinet 16′. In particular, the secondary components may be biased higher than the temperature of the reactant source vessel 10′. In one embodiment, the temperature difference between the reactant source vessel 10′ and the secondary components is greater than about 5 degrees centigrade, in another embodiment the difference is greater than about 10 degrees centigrade, and in another embodiment the difference is between about 15 and 25 degrees centigrade.

This arrangement has several advantages. For example, in the embodiment illustrated in FIGS. 1-3, when the reactant source cabinet 16′ is being cooled, the reactant source vessel 10′ tends to cool slower than the secondary components because of the reactant source vessel 10′ has a larger thermal mass. As such, the secondary components tend to fall below the vaporization temperature before the reactant source vessel 10′ falls below the vaporization temperature. This results in a situation where the reactant source vessel 10′ generates vaporized reactants that may condense in the secondary components. With the embodiment illustrated in FIGS. 6-8, the secondary components are biased by the hot plate 130 to a higher temperature than the reactant source vessel 10′. In this manner, as the reactant source cabinet 16′ is being cooled, the reactant source vessel 10′ preferably drops below the vaporizing temperature and thereby stops generating vaporized reactants before the secondary components drop the below the vaporizing temperature. This can also be accomplished (with our without the higher temperature bias) by turning off the hot plate 130 after the main heating device 32 is turned off. In this manner, the hot plate 130 may be kept on during the cool down or at least part of the cool down. In such arrangements, it may not be necessary to bias the secondary components higher than the reactant source vessel 10′ during normal operation. These arrangements therefore reduce condensation in the secondary components when the reactant source cabinet 16′ is being cooled. In a similar manner, when the reactant source cabinet is being heated the secondary components may be biased to a higher temperature than the reactant source vessel 10′ by setting their temperatures higher than the reactant source vessel 10′ and/or beginning their heating before the main heater 32 is turned on. In this manner, the secondary components reach the vaporizing temperature before the reactant source vessel 10′. This also reduces condensation in the secondary components. In one embodiment, the secondary components are kept approximately 20 degrees centigrade hotter than the reactant source vessel 10′.

It should be appreciated that in a modified embodiment, any combination or sub-combination of the secondary components described above may be arranged so as to be thermally biased by the hot plate 130. In addition, in other embodiments, other components (e.g., a filter) may be added to the secondary components and/or replace one or more of the secondary components. In certain embodiments, the hot plate 130 may be used to heat any component, upstream or downstream of the source vessel, that is susceptible to condensation because it may be exposed to the vaporized reactant through diffusion, pressure fluctuations or gas flow. It should also be appreciated a plurality of independently heated components can be positioned in the reactant source cabinet and may be used to bias the secondary components. In yet another embodiment, certain of the secondary components may be, at least partially, positioned within and/or machined and/or molded integrally with the hot plate. For example, portions of the conduits or valves may be machined into the hot plate.

It should be also appreciated that in certain embodiments the heating device 32′ and the heating device 132 of the hot plate 130 are advantageously independently controlled. As such, the apparatus 8′ includes a control system (not show) that is configured such that the heading device 132 of the hot plate 130 and the heating device 32′ may be independently controlled and/or turned on and off.

In a modified embodiment, the radiant absorption of one or more of the secondary components and/or the reactant source vessel 10′ may be modified to effectively achieve the thermal bias described above.

For example, with continued reference to FIG. 6, the reactant source vessel 10 and most of the components within the reactant source cabinet 16′ have a highly reflective outer surface that may be formed from a highly polished metal. This generally enhances the radiate scattering in the pressure vessel by promoting repeated reflection and therefore uniform radiation of all the surfaces in the pressure vessel.

However, it may be desirable to bias the heating of certain components. For example, the reactant source vessel 10′ has a high thermal mass. Therefore, as discussed above, it may be advantageous to bias the temperature of components with a lower thermal mass to a higher temperature to prevent or reduce condensation in these components as the pressure vessel is being heated or cooled. Such components may include the secondary components of the reactant source cabinet described above (e.g., control valves 70′, 76′ and portions of the conduits 20′, 24′, 206,) and in particular the secondary components downstream of the reactant source vessel 10′.

In one embodiment, these secondary components are biased to a higher temperature by decreasing the reflectivity of their outer surface. For example, the outer surface may be coated with a low reflectivity and/or a high absorptivity material that is preferably inert and durable at high temperatures. In one exemplary embodiment, a graphite or refractory powder is used which may effectively turn these components to black or near black bodies. In this manner, the radiation absorption is enhanced for these components even though they have lower thermal masses and/or exposed surface areas. In this manner, the temperature of the components with low thermal masses and/or exposed surface areas may be raised thereby reducing or eliminating cold spots in the gas delivery lines. In another embodiment, the secondary components may be made, at least in part, from a more radiant absorbent material.

It should be appreciated that the technique of varying the reflectivity of certain components of the reactant source cabinet 16′ may be used independently or in combination with the hot plate 130 described above. In addition, in a modified embodiment, certain components may be biased to a lower temperature by increasing their reflectivity (e.g., by increased or more effective polishing or using a more reflective material.)

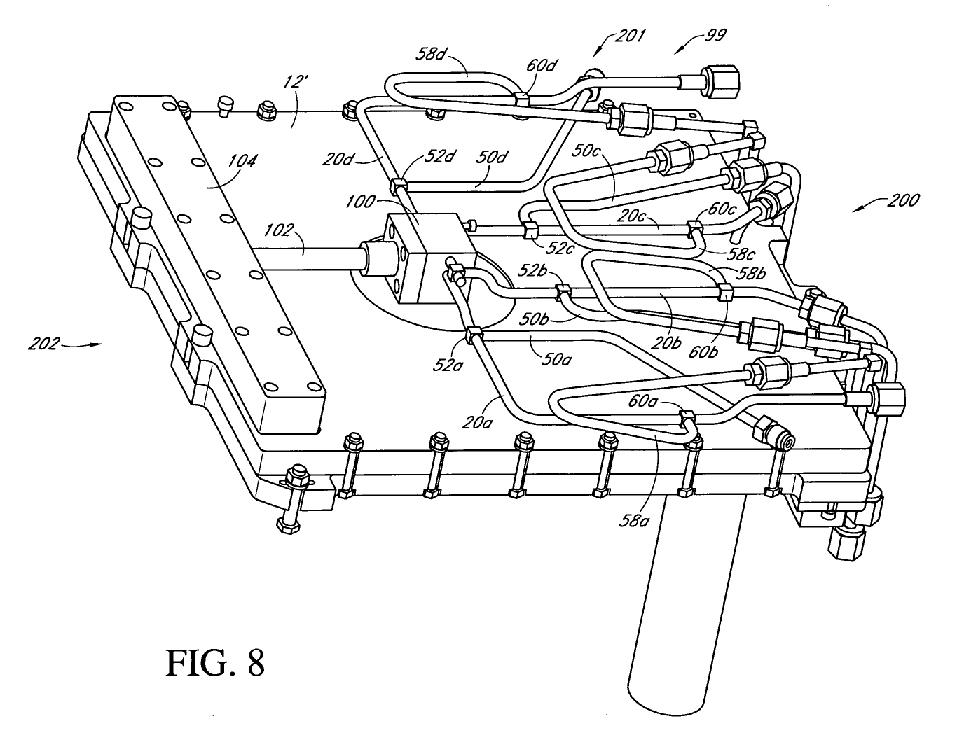

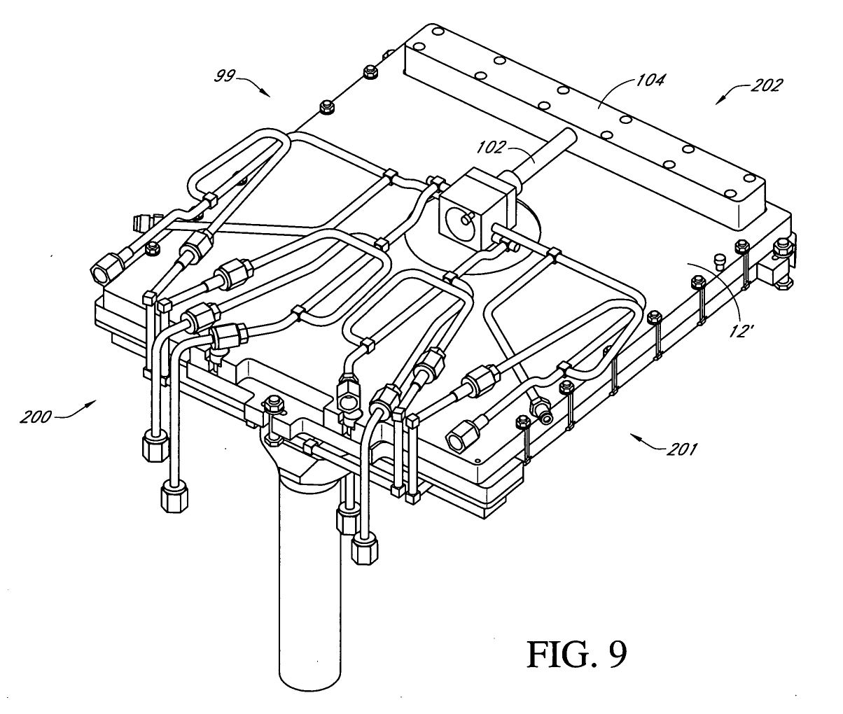

With reference now to FIGS. 8 and 9, an inert gas valving arrangement 99 is shown for a plurality of reactants. In the illustrated embodiment, each reactant includes a first conduit 20a-d, a third conduit 50a-d, a first connection point 52a-d, a second connection point 60a-d, and a fourth conduit 58a-d. The first conduits 20a-d are connected to a mixing device 100, which, in turn, is connected to a reaction chamber inlet channel 102. The reaction inlet channel 102 is connected to a distribution manifold 104, which is in communication with the interior of the reaction chamber 12′. The inert gas valving 99 illustrated in FIGS. 8 and 9 is advantageously positioned entirely or partially within the reaction chamber vessel 18′ (see FIG. 7). Advantageously, the diffusion barriers (i.e., the portion of the first conduit 20a-d between the first connection point 52a-d and the second connection point 60a-d, are located at least partially or entirely over the reaction chamber 12′ and within the reaction chamber vessel 18′.

The mixing device 100 mixes the gases from the first conduits 20a-d prior to the gases entering the deposition chamber 12′. For example, during ALD, it may be desirable to mix one reactant with an inert carrier gas flow. More particularly, although ALD reactants are not mixed in the gas phase, the fact that two ALD reactants sequentially flow through the same space in the mixer means than second reactants react with adhered first reactants on the mixer internal surfaces from the previous first reactant pulse, causing deposition. Such controllable deposition upstream of the reaction chamber is preferred as a sacrificial reaction, as compared to allowing first reactant to desorb from reaction chamber surfaces during the second reactant pulse, which can lead to uncontrolled, non-self-limiting CVD-like reactions in the chamber. The mixer chamber 100 can then be periodically cleaned. Preferably, the mixing device 100 includes a smooth interior with no or very few and/or small discontinuities. In one preferred embodiment, the mixing device comprises a conical chamber in which the reactants enter at an angle with respect to the longitudinal axis of the chamber, causing the reactants to swirl around the inner conical surfaces and funnel to the reaction inlet channel 102.

In the illustrated embodiment, portions of the first conduit 20a-d, and the third conduit 50a-d advantageously extend over the reaction chamber 12′. In certain embodiments, portions of these conduits may be thermally coupled to the reaction chamber 12′ to provide heat to the conduits. In the illustrated embodiment, several of the conduits extend (e.g., 50c, 58a, etc.) from below the reaction chamber 12′, bend approximately 90 degrees such that they can extend approximately horizontally over the reaction chamber 12 and then extend substantially horizontally from a first side of the reaction chamber 200 to the mixing device 100, which is mounted above the reaction chamber 12. Other conduits (e.g., 50a, 20c, etc.) extend substantially horizontally from the first side 200 or a second side 201 of the reaction chamber 12′ to the mixing device 100. The reaction inlet 102 extends substantially horizontally to the distribution manifold 104, which is mounted on an inlet side 202 of the reaction chamber 12′. From the distribution manifold 104, the flow of reactants is turned at an angle of greater than approximately 90 degrees and in the illustrated embodiment an angle of at least about 180 degrees while spreading out across the width of the chamber 12′ before entering the reaction chamber 12′. From there, the reactants may be discharged from an outlet positioned at the first side (or outlet end) 200 of the reaction chamber 12′. As such, many of the reactants travel horizontally over the reaction chamber 12′ from the first side 200 of the reaction chamber 12 to the inlet side 202 of the reaction chamber 12′ and then bend an angle of at least 90 degrees or in some embodiments 180 degrees before entering the reaction chamber 12′. An advantage of this is arrangement is that the vapor is preheated before entering the reaction chamber 12′, which reduces the footprint of the reactant chamber vessel 18′. Another advantage of this arrangement is that portions of the conduits extend substantially parallel to the reaction chamber 12′. In this embodiment, this is particularly advantageous when the heating elements (not shown) for the reaction chamber 12′ are positioned generally parallel to the to and bottom plates 12a, 12b which form the reaction chamber 12′. In this manner, the conduits are approximately the same distance form the heating elements and therefore capture about the same fraction of radiation from the reaction chamber 12′.

A control system (not shown) is configured to control the reaction chamber and apparatus. For example, the control system can include control software and electrically controlled valves to control the flow of reactant and purge gases into and out of the reaction chamber 12′. In one embodiment that is particularly suited for ALD reactors, the control system also controls the flow of the treatment gas into the reaction chamber 12′ to deactivate the surface against ALD reactions, such as by forming a protective layer on an inner surface of the reaction space. After deactivating the surfaces, the control system loads substrate(s) into the chamber 12′ and flows reactant and/or purge gases into the reaction chamber 12′ to form a deposit on the substrate (e.g., silicon wafer). The control system can include modules such as a software or hardware component, e.g., a FPGA or ASIC, which performs certain tasks. A module can advantageously be configured to reside on the addressable storage medium of the control system and be configured to execute on one or more processors. In certain embodiments, the control system can be advantageously configured to independently control the temperatures of the hot plate 130 and the heating device 32′ and or to independently turn on and/or off these devices.

It should be appreciated that certain features of the apparatus and methods described above can be employed in any gas phase process including, but not limited to, chemical vapor deposition (CVD). However, it is particularly suited for use in ALD reactors.

The assemblies described above may be used with a large number of solid precursors, such as metal compounds (e.g., metal halides, organometal compounds comprising metal-to-carbon bonds, metalorganic compounds that do not comprise a metal-to-carbon bond but which contain carbon (e g. thd compounds)), and elemental metals.

Although this invention has been disclosed in the context of certain preferred embodiments and exemplary embodiments, it will be understood by those skilled in the art that the present invention extends beyond the specifically disclosed embodiments to other alternative embodiments and/or uses of the invention and obvious modifications and equivalents thereof. In addition, while a number of variations of the invention have been shown and described in detail, other modifications, which are within the scope of this invention, will be readily apparent to those of skill in the art based upon this disclosure. It is also contemplated that various combination or subcombinations of the specific features and aspects of the embodiments may be made and still fall within the scope of the invention. Accordingly, it should be understood that various features and aspects of the disclosed embodiments can be combine with or substituted for one another in order to form varying modes of the disclosed invention. Thus, it is intended that the scope of the present invention herein disclosed should not be limited by the particular disclosed embodiments described above.

1. A reactant supply apparatus comprising
a vessel with a gas inlet and a gas outlet;
gas lines that are connected to the gas inlet or the gas outlet;
a plurality of components that are positioned along the gas lines;
a first heating device for heating the vessel; and
a second heating device that is controlled independently with respect to the first heating device and that is configured to heat at least one of the plurality of components.

2. A reactant supply apparatus as in claim 1, wherein the second heating device is mounted in a plate that is configured to support the vessel

3. A reactant supply apparatus as in claim 1, wherein the second heating device is mounted in a plate.

4. A reactant supply apparatus as in claim 1, further comprising a cabinet that surrounds the vessel, the first heating device and the second heating device.

5. A reactant supply apparatus as in claim 4, wherein the cabinet is kept at reduced pressure.

6. A reactant supply apparatus as in claim 4, wherein the cabinet is kept at a pressure of about 1 mTorr to 10 Torr.

7. A reactant supply apparatus as in claim 1, wherein the plurality of components include control valves for switching the flow of gas through the gas lines during operation.

8. A reactant supply apparatus as in claim 1, wherein at least one of the plurality of components is kept at a higher temperature than the vessel.

9. A reactant supply apparatus as in claim 8, wherein at least one of the plurality of components is kept greater than 5 degrees centigrade higher than the vessel.

10. A reactant supply apparatus as in claim 8, wherein at least one of the plurality of components is kept greater than 10 degrees centigrade higher than the vessel.

11. A reactant supply apparatus as in claim 8, wherein at least one of the plurality of components is kept between approximately 15 and 25 degrees centigrade higher than the vessel.

12. A processing system comprising:
a reactant source cabinet including a reactant source vessel having an inlet and an outlet and a heating device for heating the reactant source vessel within the reactant source cabinet;
an inert gas source;
a reaction chamber vessel comprising a reaction chamber;
a first conduit for connecting the reactant source vessel to the reaction chamber;
a second conduit for connecting the inert gas source to the first conduit at a first connection point;
a third conduit for connecting the first conduit to a drain at a second connection point,
wherein a portion of the first conduit between the first and the second connection points is located at least partially within the reaction chamber vessel.

13. A processing system as in claim 12, wherein the reaction chamber is an ALD reaction chamber.

14. A processing system as in claim 12, wherein the second connection point is located upstream of the first connection point.

15. A processing system as in claim 12, wherein the portion of the first conduit between the first and the second connection points is located above the reaction chamber.

16. A reactant supply apparatus comprising
an enclosure;
a reactant source vessel with a gas inlet and a gas outlet positioned in the enclosure;
gas lines that are connected to the gas inlet and the gas outlet positioned in the enclosure;
a plurality of components that are positioned along the gas lines within the enclosure; and
a radiant heating device positioned within the enclosure,
wherein at least a portion of the gas lines or at least one of the plurality of components have a higher absorptivity than the reactant source vessel.

17. The reactant supply apparatus as in claim 16, wherein the at least a portion of the gas lines or the at least one of the plurality of components with a higher absorptivity are positioned downstream of the reactant source vessel.

18. The reactant supply apparatus as in claim 16, wherein the higher absorptivity is provided by coating the at least a portion of the gas lines or the at least one of the plurality of components with an inert coating.

19. The reactant supply apparatus as in claim 16, wherein the inert coating comprises graphite.

20. The reactant supply apparatus as in claim 16, wherein the inert coating comprises a refractory powder.

21. A reactant supply apparatus as in claim 16, wherein the enclosure is kept at a reduced pressure.

22. A reactant supply apparatus as in claim 16, wherein the at least one of the plurality of components include control valves for switching the flow of gas through the gas lines during operation.

23. A reactant supply apparatus comprising
an enclosure;
a reactant source vessel with a gas inlet and a gas outlet positioned in the enclosure;
gas lines that are connected to the gas inlet and the gas outlet positioned in the enclosure;
a plurality of components that are positioned along the gas lines within the enclosure; and
a radiant heating device positioned within the enclosure,
wherein at least a portion of the gas lines or at least one of the plurality of components have a higher absorptivity than the reactant source vessel.

24. An apparatus for supplying a vaporized reactant to a reaction chamber, comprising:
a source of the vaporized reactant;
a plurality of components through which the vaporized reactant flow towards the reaction chamber; and
a radiant heat source for heating at least some of the plurality of components,
wherein at least one of the plurality of components is coated with a coating that increases its absorptivity.

25. A reactant supply apparatus comprising
a vessel with a gas inlet and a gas outlet;
gas lines that are connected to the gas inlet or the gas outlet;
a plurality of components that are positioned along the gas lines;
a first heating device for heating the vessel; and
means for biasing the temperature of at least one of the plurality of components to a temperature higher than the vessel.
